(19) United States
(12) Patent Application Publication
(10) Pub. No.: US 2024/0412991 A1
(43) Pub. Date: Dec. 12, 2024

(54) MAGNETIC BONDING STRUCTURE AND METHOD OF FORMING SAME

(71) Applicant: Taiwan Semiconductor Manufacturing Co., Ltd., Hsinchu (TW)

(72) Inventors: Tsung-En Lee, Taipei City (TW); MingYuan Song, Hsinchu (TW); Hung-Li Chiang, Taipei City (TW); Jer-Fu Wang, Taipei City (TW); Chao-Ching Cheng, Hsinchu (TW); Iuliana Radu, Zhubei City (TW)

(21) Appl. No.: 18/491,237

(22) Filed: Oct. 20, 2023

Related U.S. Application Data
(60) Provisional application No. 63/506,896, filed on Jun. 8, 2023.

(51) Int. Cl. H01L 21/67; H01L 21/768; H01L 23/00; H01L 23/48; H01L 23/498; H01L 25/065

(52) U.S. Cl. CPC H01L 21/67259; H01L 21/76898; H01L 23/481; H01L 23/49861; H01L 24/09; H01L 25/0657; H01L 2924/01026

(57) ABSTRACT

A method includes forming first bonding pads over a first substrate, wherein the first bonding pads include a layer of ferromagnetic material, wherein each first bonding pad produces a respective magnetic field having a first orientation; and bonding second bonding pads to the first bonding pads using metal-to-metal bonding.

### PRIORITY CLAIM AND CROSS-REFERENCE

This application claims the benefit of U.S. Provisional Application No. 63/506,896, filed on Jun. 8, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a wafer with magnetic bonding pads, in accordance with some embodiments.

FIG. 2 illustrates a plan view of a wafer with magnetic bonding pads, in accordance with some embodiments.

FIGS. 3A and 3B illustrate cross-sectional views of intermediate steps of a bonding process, in accordance with some embodiments.

FIGS. 4A and 4B illustrate cross-sectional views of intermediate steps of a bonding process, in accordance with some embodiments.

FIGS. 5A and 5B illustrate cross-sectional views of intermediate steps of a bonding process, in accordance with some embodiments.

FIGS. 6A, 6B, 6C, and 6D illustrate plan views of wafers with magnetic bonding pads, in accordance with some embodiments.

FIGS. 7A and 7B illustrate perspective views of intermediate steps of a bonding process, in accordance with some embodiments.

FIGS. 8A and 8B illustrate simulation data for a bonding process, in accordance with some embodiments.

FIGS. 9, 10, 11, 12, 13, and 14 illustrate cross-sectional views of intermediate steps in the formation of magnetic bonding pads, in accordance with some embodiments.

FIGS. 15A and 15B illustrate cross-sectional views of intermediate steps in the formation of magnetic bonding pads, in accordance with some embodiments.

FIGS. 16, 17, 18, 19, and 20 illustrate cross-sectional views of intermediate steps in the formation of magnetic bonding pads, in accordance with some embodiments.

FIGS. 21, 22, 23, 24, and 25 illustrate cross-sectional views of intermediate steps in the formation of magnetic bonding pads, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, magnetic bonding pads are formed in a die or wafer. The magnetic bonding pads may be bonded to corresponding magnetic bonding pads of another die or wafer using metal-to-metal bonding techniques. During the bonding process, each pair of corresponding magnetic bonding pads are attracted to each other by magnetic force. The magnetic attraction pulls the magnetic bonding pads into relative alignment which each other during the bonding process. In this manner, misalignment of the bonded wafers or dies may be reduced. The magnetic bonding pads may be electrically connected to other features within the wafer or die or may be dummy bonding pads. Intermediate stages in the formation of magnetic bonding pads are illustrated in accordance with some embodiments. Some variations of some embodiments are discussed. Throughout the various views and illustrative embodiments, like reference numbers are used to designate like elements.

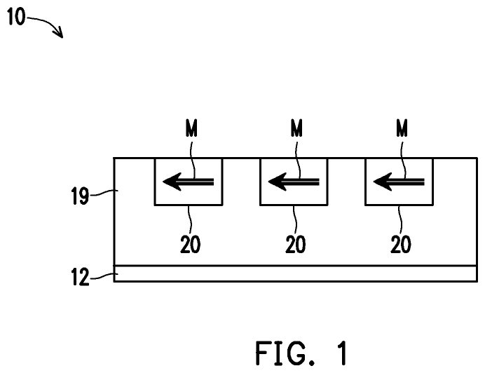

FIG. 1 illustrates a cross-sectional view of a wafer 10 comprising magnetic bonding pads 20, in accordance with some embodiments. The wafer 10 shown in FIG. 1 is an illustrative example, and accordingly the dimensions, numbers, shapes, configurations, compositions, and/or arrangements of the various features may be different than shown. Additionally, some features of wafer 10 may be omitted for clarity, and some features of wafer 10 are explained in greater detail below. The wafer 10 may include different device regions that are subsequently singulated to form a plurality of individual integrated circuit dies (e.g., chips, devices, packages, or the like). FIG. 1 may represent an entire wafer or a portion thereof, a device region or a portion thereof, or an individual die or a portion thereof. Thus, the term “wafer” as used herein may also represent a die, chip, device, package, interposer, or any other suitable structure.

Wafer 10 comprises a substrate 12, which may have active and/or passive devices formed therein. A plurality of interconnections (e.g., conductive lines, vias, contacts, or the like) may be formed over the substrate 12 and may interconnect the devices. A plurality of dielectric layers 19 are formed over the substrate, and the interconnections may be formed in the dielectric layers 19. The dielectric layers 19 may include, for example, Inter-Layer Dielectric (ILD) layers and/or Inter-Metal Dielectric (IMD) layers. In some cases, the top-most dielectric layer of the dielectric layers 19 may comprise a material suitable for dielectric-to-dielectric bonding (e.g., insulator-to-insulator bonding, oxide-to-oxide bonding, fusion bonding, direct bonding, hybrid bonding, or the like). In some cases, this top-most dielectric layer may be referred to as a “bonding layer” herein.

As shown in FIG. 1, the wafer 10 may include one or more magnetic bonding pads 20 formed at a front side of the wafer 10 (e.g., the surface facing upwards in FIG. 1, also called a “top side”). The magnetic bonding pads 20 may be formed at least partially in the top-most dielectric layer of the dielectric layers 19, in some embodiments. The magnetic bonding pads 20 are conductive features that are subsequently bonded to the magnetic bonding pads of another wafer to form, for example, a bonded structure or package. In this manner, the magnetic bonding pads 20 may comprise a material suitable for metal-to-metal bonding (e.g., fusion bonding, direct bonding, hybrid bonding, or the like). The magnetic bonding pads 20 may be electrically coupled to the interconnections and/or devices of the wafer 10, in some embodiments. In other embodiments, one or more of the magnetic bonding pads 20 are electrically isolated from the interconnections and devices of the wafer 10, and thus may be considered “dummy bonding pads.”

Further, the magnetic bonding pads 20 comprise magnetic material(s) or magnetic structures that produce a magnetic field. The magnetic bonding pads 20 are formed such that the magnetic fields produced by each magnetic bonding pad 20 are similar. In FIG. 1, the magnetic field produced by each magnetic bonding pad 20 is indicated by an arrow (labeled “M” in FIG. 1) representing the orientation of that magnetic field. For example, each arrow M points in a direction from the south pole of the corresponding magnetic field toward the north pole of the corresponding magnetic field. In this manner, an arrow M may be considered a representation of the magnetic moment of the magnetic field, in some cases. In FIG. 1, the magnetic fields of the magnetic bonding pads 20 are oriented in a lateral direction, but other orientations are possible. Subsequent figures use arrows M to represent the orientations of the magnetic fields (where present) of magnetic bonding pads 20. In some embodiments, the magnetic fields of the magnetic bonding pads 20 may be oriented by performing a magnetic annealing process, described in greater detail below.

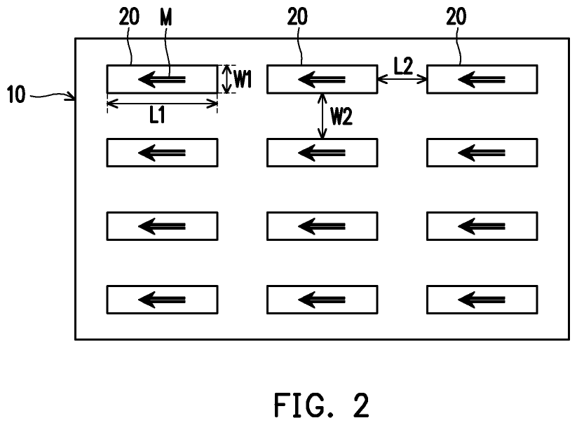

FIG. 2 illustrates a plan view of a wafer 10, in accordance with some embodiments. The wafer 10 of FIG. 2 may be similar to the wafer 10 of FIG. 1 or other wafers described herein. As shown in FIG. 2, the wafer 10 comprises a plurality of magnetic bonding pads 20 that each have a magnetic field oriented in approximately the same direction. For example, the magnetic fields of the magnetic bonding pads 20 of FIG. 2 are all oriented in a lateral direction (e.g., approximately parallel to the front surface of the wafer 10). In other embodiments, the magnetic fields of the magnetic bonding pads 20 may be oriented in a different direction than shown. Other numbers, dimensions, shapes, configurations, or arrangements of magnetic bonding pads 20 are possible.

For some embodiments in which the magnetic bonding pads 20 are formed as part of a Front End of Line (FEOL) process, the magnetic bonding pads 20 may have a length L1 in the range of about 10 nm to about 500 nm or a width W1 in the range of about 10 nm to about 500 nm. For some embodiments in which the magnetic bonding pads 20 are formed as part of a Back End of Line (BEOL) process, the magnetic bonding pads 20 may have a length L1 in the range of about 1 μm to about 100 μm or width W1 in the range of about 1 μm to about 100 μm. In some embodiments, the magnetic bonding pads 20 may be separated from each other by a length L2 in the range of about 10 nm to about 100 μm or a width W2 in the range of about 10 nm to about 100 μm. Other dimensions or separations are possible. In some embodiments, the magnetic bonding pads 20 may be rectangular in a plan view, such that the ratio L1/W1 is greater than 1, though other shapes are possible. In some embodiments, the longest lateral dimension of a magnetic bonding pad 20 may be approximately parallel to the orientation of its magnetic field. For example, in FIG. 2, the longest lateral dimension of the magnetic bonding pads 20 is the length L1, which is approximately parallel to the arrow M representing the orientation of the magnetic field.

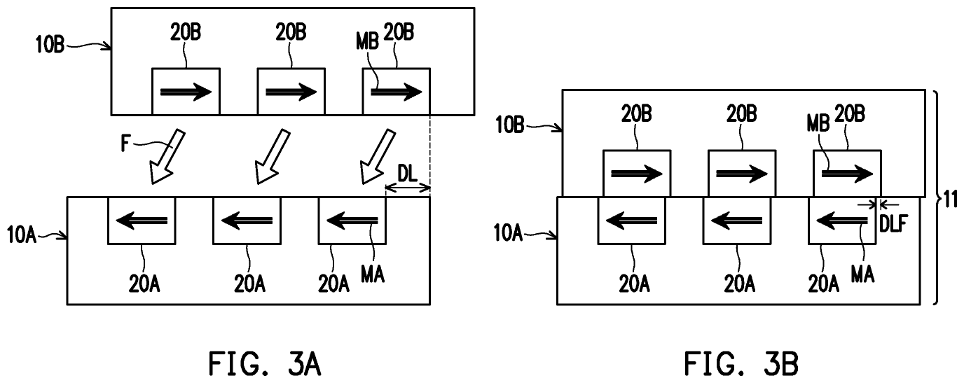

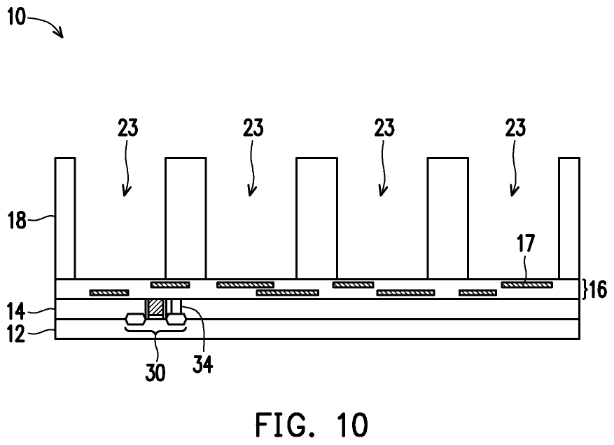

FIGS. 3A and 3B illustrate intermediate steps of bonding a first wafer 10A to a second wafer 10B to form a bonded structure 11, in accordance with some embodiments. The wafers 10A-B may be similar to the wafer 10 described for FIG. 10 or other wafers described elsewhere herein. For example, the first wafer 10A includes magnetic bonding pads 20A, and the second wafer 10B includes magnetic bonding pads 20B. The magnetic bonding pads 20A-B may be similar to the magnetic bonding pads 20 described for FIG. 1 or other magnetic bonding pads described elsewhere herein. For example, the magnetic bonding pads 20A-B in FIGS. 3A-3B have magnetic fields oriented in lateral directions, as indicated by arrows MA and MB. The bonding process shown and described for FIGS. 3A-3B is an illustrative example, and other structures or processes are possible.

FIG. 3A shows the first wafer 10A and the second wafer 10B prior to bonding, in accordance with some embodiments. The second wafer 10B has been flipped upside-down such that the front side of the second wafer 10B faces the front side of the first wafer 10A. In other words, the bonding layer (not separately illustrated) of the first wafer 10A faces the bonding layer (not separately illustrated) of the second wafer 10B, and each magnetic bonding pad 20A of the first wafer 10A faces a corresponding magnetic bonding pad 20B of the second wafer 10B.

Prior to bonding, the magnetic fields of magnetic bonding pads 20B of the second wafer 10B are oriented in direction that is opposite to the orientation of the magnetic fields of the magnetic bonding pads 20A. Because the magnetic fields of the magnetic bonding pads 20B are opposite to the magnetic fields of the magnetic bonding pads 20A, the magnetic bonding pads 20B experience a magnetic force that attracts the magnetic bonding pads 20B toward corresponding magnetic bonding pads 20A. In other words, the north pole of each magnetic bonding pad 20B is attracted to the south pole of a corresponding magnetic bonding pad 20A, and the south pole of that magnetic bonding pad 20B is also attracted to the north pole of that corresponding magnetic bonding pad 20A. This attractive force between pairs of magnetic bonding pads 20A-B pulls each magnetic bonding pad 20B toward its corresponding magnetic bonding pad 20A during bonding, which can improve alignment between the magnetic bonding pads 20A-B and thus improve alignment of the wafers 10A-B of the bonded structure 11. This is indicated in FIG. 3A by arrows F representing the magnetic attraction of the magnetic bonding pads 20B toward corresponding magnetic bonding pads 20A. FIG. 3A also shows the lateral misalignment DL between the magnetic bonding pads 20A and the magnetic bonding pads 20B prior to bonding.

During the bonding process, the magnetic bonding pads 20B of the second wafer 10B are directly bonded (e.g., using metal-to-metal bonding) to the magnetic bonding pads 20A of the first wafer 10A. In this manner, the magnetic bonding pads 20A-B may physically and electrically connect the wafers 10A-B. In some embodiments, the bonding layer (e.g., the top-most dielectric layer) of the second wafer 10B are also directly bonded (e.g., using dielectric-to-dielectric bonding) to the bonding layer of the first wafer 10A.

As an example, the bonding process may include performing a surface treatment to the bonding layer of the first wafer 10A and/or the bonding layer of the second wafer 10B. The surface treatment may include, for example, a plasma treatment. The plasma treatment may be performed in a vacuum environment. After the plasma treatment, the surface treatment may further include a cleaning process (e.g., a rinse with deionized water, or the like). The magnetic bonding pads 20B may then be aligned to the magnetic bonding pads 20A. When the magnetic bonding pads 20B and the magnetic bonding pads 20A are aligned, the magnetic bonding pads 20B may vertically overlap the corresponding magnetic bonding pads 20A, as shown in FIG. 3A. In some cases, the magnetic bonding pads 20B may also have a lateral offset from a desired or ideal alignment position relative to the magnetic bonding pads 20A, shown in FIG. 3A as the misalignment DL.

The second wafer 10B may then be brought into contact with the first wafer 10A. For example, the bonding layer of the second wafer 10B may be brought into contact with the bonding layer of the first wafer 10A, and the magnetic bonding pads 20B may be brought into contact with the magnetic bonding pads 20A. Due to the magnetic attraction between the magnetic bonding pads 20A-B, the second wafer 10B experiences lateral and vertical forces while being brought into contact with the first wafer 10A. In some embodiments, the second wafer 10B is supported by a holder that allows the magnetic forces to laterally translate the second wafer 10B. These magnetic forces translate the magnetic bonding pads 20B such that misalignment between the magnetic bonding pads 20A and the magnetic bonding pads 20B is reduced. This is shown in FIG. 3B by the final misalignment DLF, which is less than the misalignment DL prior to bonding shown in FIG. 3A. In this manner, the use of magnetic bonding pads can reduce misalignment, which can increase surface area contact between the bonding pads of the bonded wafers, which can reduce resistance, improve device performance, and improve yield. The misalignments DL and DLF shown in FIGS. 3A-3B are intended as illustrative examples, and other misalignments are possible.

In some embodiments, the bonding layer of the second wafer 10B bonds to the bonding layer of the first wafer 10A upon contact. In this manner, the second wafer 10B may be bonded to the first wafer 10A using dielectric-to-dielectric bonding. In some embodiments, the dielectric-to-dielectric bonding process is performed at room temperature. In some embodiments, an annealing process is subsequently performed to strengthen the dielectric-to-dielectric bonds. In some embodiments, the magnetic bonding pads 20B are bonded to the magnetic bonding pads 20A by performing an annealing process once the wafers 10A-B are in contact. In this manner, the second wafer 10B may be bonded to the first wafer 10A using metal-to-metal bonding. In some cases, the annealing process for the metal-to-metal bonding may be the same annealing process used for the dielectric-to-dielectric bonding. In some embodiments, the annealing process includes a temperature in the range of about 50° C. to about 1200° C., though other temperatures are possible. The particular temperature(s) used for the annealing process may depend on the material(s) of the magnetic bonding pads 20A-B, in some cases. As shown in FIG. 3B, in some cases, the bonding layer of one wafer may physically contact a magnetic bonding pad of the other wafer due to misalignment. In this manner, a bonded structure 11 may be formed by bonding the first wafer 10A to the second wafer 10B using dielectric-to-dielectric bonding and metal-to-metal bonding (e.g., “hybrid bonding”). This is an example, and other bonding processes are possible. The bonded structure 11 may be subsequently processed using suitable processing steps to form a package or the like.

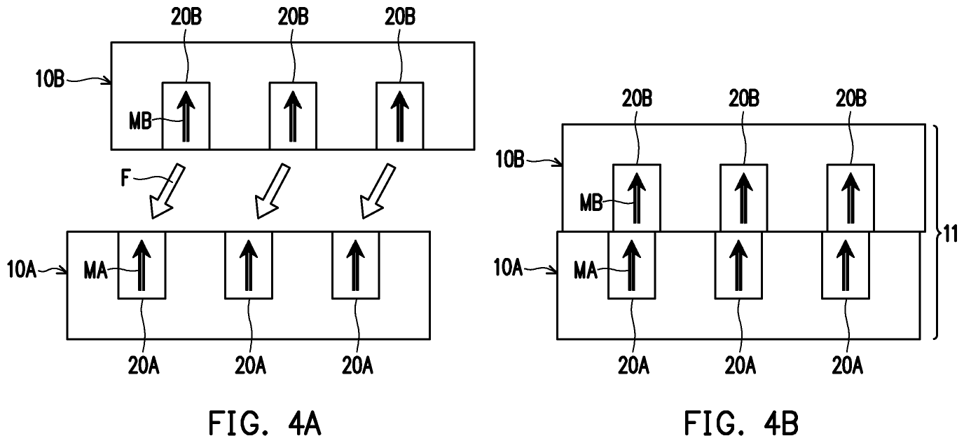

FIGS. 4A and 4B illustrate intermediate steps of bonding a first wafer 10A to a second wafer 10B to form a bonded structure 11, in accordance with some embodiments. The wafers 10A-B are similar to the wafers 10A-B described for FIGS. 1-3B, except that the magnetic fields of the magnetic bonding pads 20A-B are oriented vertically rather than laterally, as indicated by arrows MA and MB. For example, in FIGS. 4A-4B, the magnetic fields of the magnetic bonding pads 20A-B are oriented such that the north poles of the magnetic bonding pads 20A face the south poles of the magnetic bonding pads 20B. In some cases, magnetic bonding pads having vertically-oriented magnetic fields may experience greater vertical attractive forces than magnetic bonding pads having laterally-oriented magnetic fields. The wafers 10A-B of FIGS. 4A-4B may be bonded using dielectric-to-dielectric bonding and metal-to-metal bonding techniques similar to those described for FIGS. 3A-3B.

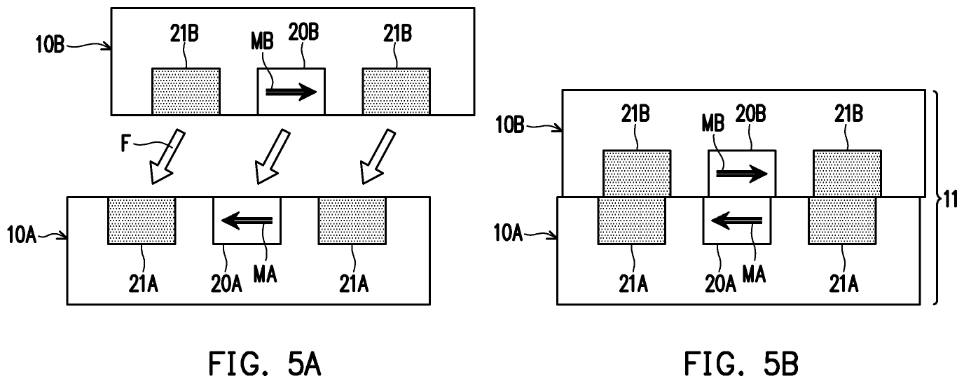

FIGS. 5A and 5B illustrate intermediate steps of bonding a first wafer 10A to a second wafer 10B to form a bonded structure 11, in accordance with some embodiments. The wafers 10A-B are similar to the wafers 10A-B described for FIGS. 1-3B, except that the wafers 10A-B include nonmagnetic bonding pads 21A-B in addition to magnetic bonding pads 20A-B. The nonmagnetic bonding pads 21A-B may be electrically connected to interconnections and/or devices within each wafer 10A-B. In some embodiments, each nonmagnetic bonding pad 21A of the first wafer 10A is bonded to a corresponding nonmagnetic bonding pad 21B of the second wafer 10B, and each magnetic bonding pad 20A of the first wafer 10A is bonded to a corresponding magnetic bonding pad 20B of the second wafer 10B. The wafers 10A-B of FIGS. 5A-5B may be bonded using dielectric-to-dielectric bonding and metal-to-metal bonding techniques similar to those described for FIGS. 3A-3B or 4A-4B.

In some cases, the use of both magnetic bonding pads and nonmagnetic bonding pads can allow for the magnetic attractive forces of the magnetic bonding pads to improve alignment as described previously while also allowing for metal-to-metal bonding using nonmagnetic materials. In some cases, bonding using some nonmagnetic materials can improve metal-to-metal bonding and reduce resistance of the bond. In this manner, the alignment of bonded wafers in a bonded structure can be improved, and the device performance of a bonded structure can be improved.

The nonmagnetic bonding pads 21A-B may be formed of one or more nonmagnetic materials, such as copper, aluminum, or the like. The nonmagnetic bonding pads 21A-B may be formed using some of the same processing steps used to form the magnetic bonding pads 20A-B, in some embodiments. In some embodiments, the magnetic bonding pads may be electrically isolated from interconnections and/or devices within the wafer. In these embodiments, the nonmagnetic bonding pads provide electrical connection between the bonded wafers, and the magnetic bonding pads may be considered “dummy bonding pads.” Some embodiments may include both dummy magnetic bonding pads and non-dummy magnetic bonding pads. In some embodiments, a bonded structure may comprise a magnetic bonding pad bonded to a nonmagnetic bonding pad.

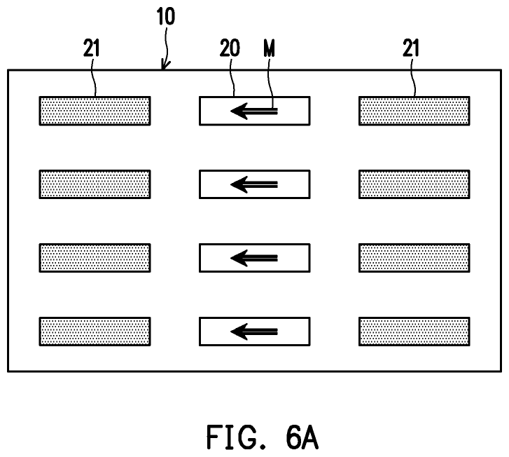

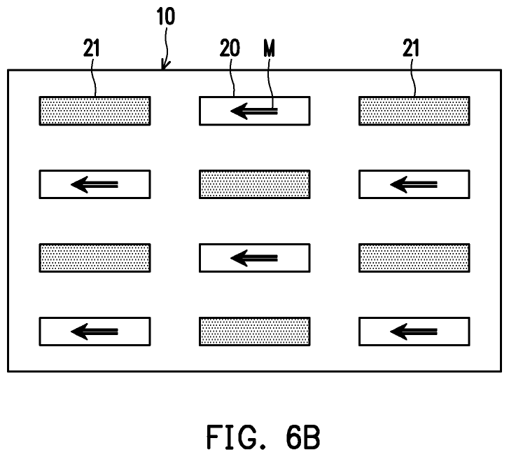

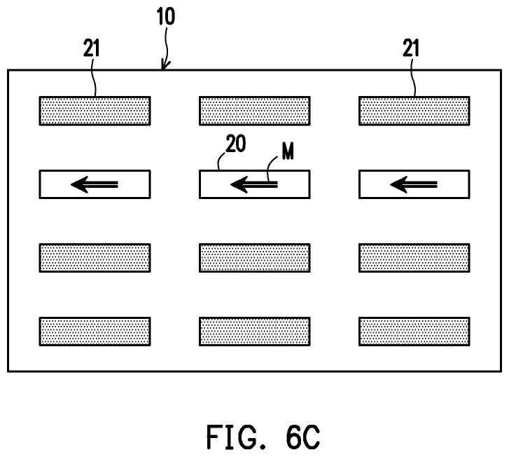

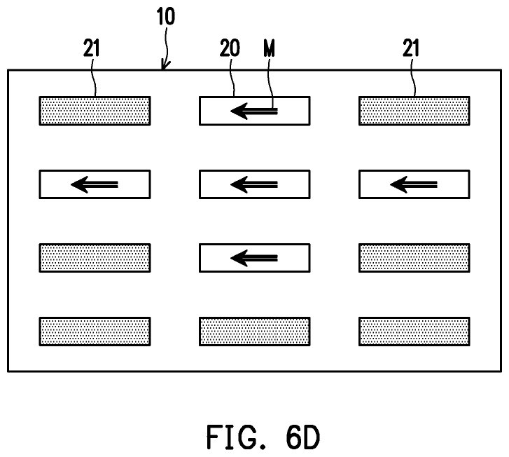

FIGS. 6A through 6D illustrate plan views of wafers 10 that include magnetic bonding pads 20 and nonmagnetic bonding pads 21, in accordance with some embodiments. The wafers 10 of FIG. 6A-6D may be similar to the first wafer 10A or the second wafer 10B described for FIGS. 5A-5B. As shown in FIGS. 6A-6D, the magnetic bonding pads 20 and the nonmagnetic bonding pads 21 may have a variety of arrangements. For example, in some embodiments, magnetic bonding pads 20 may be arranged in columns (such as FIG. 6A), staggered (such as FIG. 6B), in rows (such as FIG. 6C), in “clusters” (such as FIG. 6D), or in any other suitable arrangement. In some embodiments, some magnetic bonding pads 20 may be arranged relatively near other magnetic bonding pads 20 to enhance magnetic attraction forces during bonding. FIGS. 6A-6D are intended as non-limiting examples, and other numbers, dimensions, shapes, configurations, or arrangements of magnetic bonding pads 20 and nonmagnetic bonding pads 21 are possible.

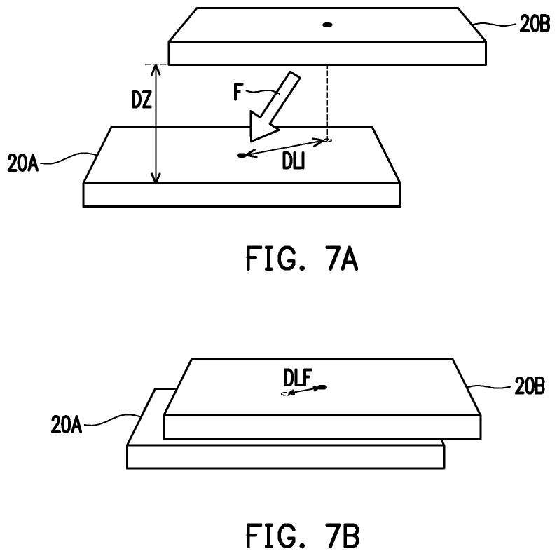

FIGS. 7A and 7B are three-dimensional views of intermediate steps in the bonding of a first magnetic bonding pad 20A to a second magnetic bonding pad 20B, in accordance with some embodiments. The magnetic bonding pads 20A-B may be similar to other magnetic bonding pads described herein. FIG. 7A illustrates the magnetic bonding pads 20A-B prior to bonding, similar to FIG. 3A, and FIG. 7B illustrates the magnetic bonding pads 20A-B after bonding, similar to FIG. 3B. The magnetic bonding pads 20A-B may be bonded using techniques similar to those described previously for FIGS. 30A-B. As shown in FIG. 7A, prior to bonding, the magnetic bonding pads 20A-B are vertically separated by a distance DZ and have an initial lateral misalignment DLI. The magnetic bonding pad 20B is pulled toward the magnetic bonding pad 20A by a magnetic attraction (indicated by arrow F). As shown in FIG. 7B, after bonding, the magnetic bonding pads 20A-B are in contact (e.g., DZ is zero) and have a final lateral misalignment DLF. As described previously, the magnetic attraction between the magnetic bonding pads 20A-B during the bonding process reduces the misalignment from the initial lateral misalignment DLI to a final lateral misalignment DLF that is smaller than the initial lateral misalignment DLI.

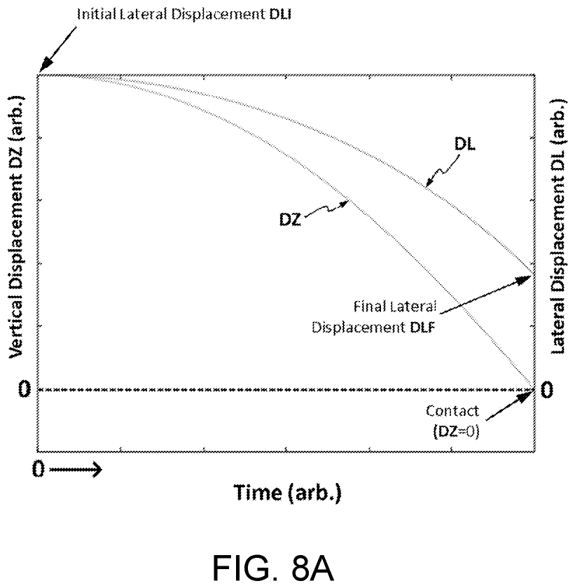

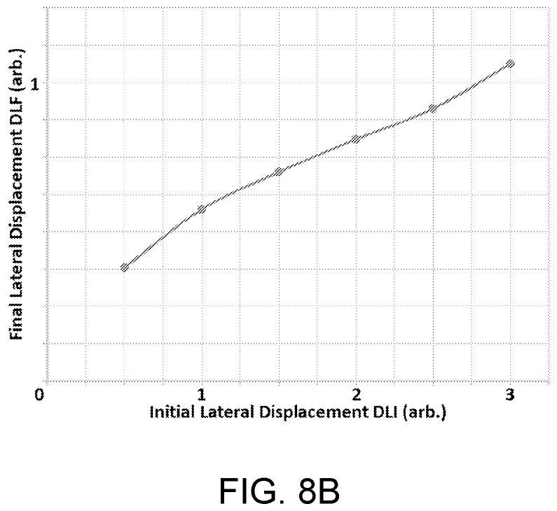

FIGS. 8A and 8B illustrate simulation data of the bonding of magnetic bonding pads, in accordance with some embodiments. The simulation data shown in FIGS. 8A-8B are examples shown for explanatory purposes, and other simulations may produce other data in other cases, such as for other configurations or characteristics of the magnetic bonding pads. FIG. 8A illustrates simulation data of the displacement of an overlying magnetic bonding pad (e.g., magnetic bonding pad 20B of FIGS. 7A-7B) as it is brought into contact with an underlying magnetic bonding pad (e.g., magnetic bonding pad 20A of FIGS. 7A-7B) during a bonding process. For example, FIG. 8A illustrates the vertical displacement DZ (see FIGS. 3A and 7A) and the lateral displacement DL (see FIGS. 3A-3B and 7A-7B) of the overlying magnetic bonding pad relative to the underlying magnetic bonding pad. In particular, FIG. 8A shows the vertical displacement DZ and the lateral displacement DL over time from initial values until the magnetic bonding pads make contact at DZ=o. As shown in FIG. 8A, the magnetic attraction between the magnetic bonding pads causes the lateral displacement DL to decrease from the initial lateral displacement DLI to the final lateral displacement DLF. The final lateral displacement DLF may be different in other cases. As shown in FIG. 8A, the magnetic forces between the magnetic bonding pads may be stronger when the vertical displacement DZ is smaller, and thus both the lateral displacement DL and the vertical displacement DZ decrease more rapidly over time.

FIG. 8B illustrates a relationship between the initial lateral displacement DLI and the final lateral displacement DLF for a pair of magnetic bonding pads. The x-axis is the initial lateral displacement DLI in arbitrary units, and the y-axis is the final lateral displacement DLF in the same arbitrary units. As shown in FIG. 8B, the magnetic attraction between the magnetic bonding pads reduces the misalignment for a variety of initial lateral displacements DLI. As shown in FIG. 8B, in some cases, the reduction in misalignment relative to the initial lateral displacement DLI is greater for a larger initial lateral displacement DLI. In some cases, the techniques described herein allow for a final lateral displacement DLF that is between about 60% and about 95% of the initial lateral displacement DLI. Other percentages are possible.

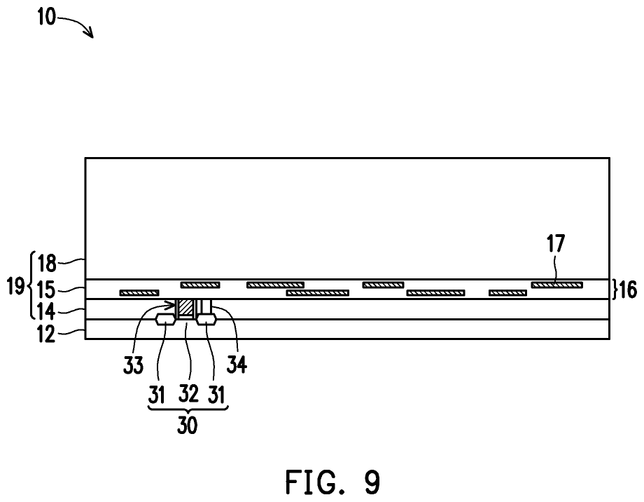

FIGS. 9 through 16 illustrate intermediate steps in the formation of magnetic bonding pads 20 (see FIG. 16) in a wafer 10, in accordance with some embodiments. The magnetic bonding pads 20 and the wafer 10 may be similar to those described previously. The process steps, magnetic bonding pads 20, and wafer 10 illustrated in FIGS. 9-16 are an example, and other processes, structures, features, or characteristics thereof are possible.

FIG. 9 illustrates a cross-sectional view of wafer 10, in accordance with some embodiments. In accordance with some embodiments of the present disclosure, wafer 10 is or comprises a device wafer including active devices and possibly passive devices, which are represented as integrated circuit devices 30. Wafer 10 may include a plurality of integrated circuit dies therein, with one of integrated circuit dies being illustrated. The wafer 10 may include different device regions that are singulated in subsequent steps to form a plurality of integrated circuit dies. The wafer 10 may be processed according to applicable manufacturing processes to form integrated circuits, and may be packaged in subsequent processing to form an integrated circuit package.

In some embodiments, the wafer 10 comprises a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. In accordance with alternative embodiments of the present disclosure, wafer 10 is an interposer wafer, which is free from active devices, and may or may not include passive devices.

In some embodiments, the wafer 10 includes a substrate 12. In some embodiments, the substrate 12 is a semiconductor substrate, such as silicon, doped or undoped, or an active layer of a semiconductor-on-insulator (SOI) substrate. The substrate 12 may include other semiconductor materials, such as germanium; a compound semiconductor including silicon carbide, gallium arsenic, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The substrate 12 has an active surface (e.g., the surface facing upwards in FIG. 9), sometimes called a front side, and an inactive surface (e.g., the surface facing downwards in FIG. 9), sometimes called a back side. In other embodiments, the substrate 12 is a material other than a semiconductor material.

Devices may be formed at the front surface of the substrate 12. In FIG. 9, the devices are represented by a transistor 30. The devices may be active devices and/or passive devices. A wide variety of devices such as transistors (e.g., finFETs, planar FETs, nanostructure (e.g., nanosheet, nanowire, gate-all-around, or the like) field effect transistors (NSFETs), or the like), diodes, capacitors, resistors, combinations of these, and the like may be used to generate the structural and functional requirements of the design for the wafer 10. The devices may be formed using any suitable methods. In accordance with alternative embodiments, wafer 10 is used for forming interposers (which are free from active devices), and substrate 12 may be a semiconductor substrate or a dielectric substrate.

An inter-layer dielectric (ILD) 14 may be formed over the front surface of the substrate 12. The ILD 14 surrounds and may cover the devices. The ILD 14 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like. The ILD 14 may be formed using a deposition method such as Plasma Enhanced Chemical Vapor Deposition (PECVD), Low Pressure Chemical Vapor Deposition (LPCVD), or the like.

Conductive plugs 34 extend through the ILD 14 to electrically and physically couple the devices. For example, when the devices are transistors, the conductive plugs 34 may couple the gates 33 and source/drain regions 31 of the transistors 30. Source/drain region(s) 31 may refer to a source or a drain, individually or collectively dependent upon the context. The conductive plugs 34 may be formed of tungsten, cobalt, nickel, copper, silver, gold, aluminum, the like, or combinations thereof. An interconnect structure 16 is over the ILD 14 and conductive plugs 34. The interconnect structure 16 interconnects the devices to form an integrated circuit. The interconnect structure 16 may be formed as part of a FEOL process and/or as part of a BEOL process. The interconnect structure 16 may be formed of metallization patterns 17 in dielectric layers 15 on the ILD 14. For example, the interconnect structure may be formed of alternating layers of dielectric material (e.g., low-k dielectric material) and conductive material (e.g., copper) with vias interconnecting the layers of conductive material. The dielectric layers 15 may be Inter-Metal Dielectric (IMD) layers, in some embodiments. The metallization patterns 17 may be formed through any suitable process, such as deposition, damascene, dual damascene, or the like. In some cases, the interconnect structure 16 may be considered a redistribution structure or the like.

A dielectric layer 18 may be formed over the interconnect structure 16, in some embodiments. The dielectric layer 18 may comprise one or more layers of dielectric materials, such as silicon oxide, low-temperature silicon oxide (LTO), silicon nitride, low-temperature silicon nitride (LTN), silicon oxynitride, polymer, the like, or a combination thereof. In some cases, the dielectric layer 18 may be a dielectric layer of the dielectric layers 15. In some embodiments, the dielectric layer 18 or the topmost layer of the dielectric layer 18 is a bonding layer (not separately illustrated) comprising material suitable for achieving a dielectric-to-dielectric bond. For example, the bonding layer may comprise silicon oxide, silicon nitride, silicon oxynitride, or the like, which may be deposited using a suitable deposition process such as PVD, CVD, ALD, or the like. Other materials are possible. In some embodiments, the dielectric layer 18 has a thickness in the range of about 10 nm to about 100 μm, though other thicknesses are possible. The ILD 14, dielectric layers 15, and/or dielectric layer 18 may be collectively referred to as the dielectric layers 19 herein.

In FIG. 10, openings 23 are formed in the dielectric layer 18, in accordance with some embodiments. The openings 23 may be recesses or trenches that expose underlying conductive features such as metallization patterns 17 of the interconnect structure 16 and/or conductive plugs 34. The openings 23 may be formed, for example, by depositing a mask material (not shown) over the dielectric layer 18 and then patterning the mask material to form a patterned mask. The mask material may comprise, for example, a photoresist material and/or a hard mask material. An etching process may then be performed using the patterned mask to form the openings 23. The etching process may include a wet etching process and/or a dry etching process, which may be anisotropic.

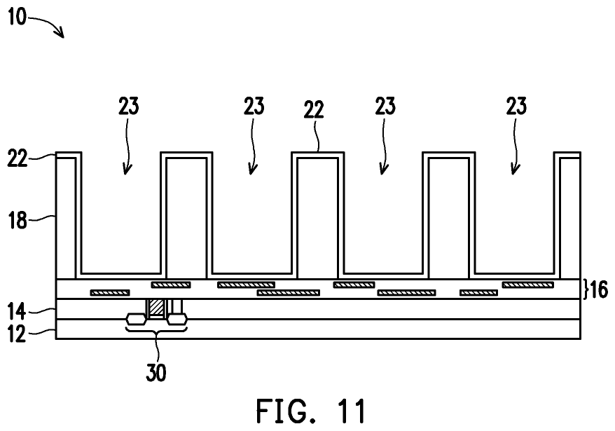

In FIG. 11, an adhesion layer 22 is deposited in the openings 23, in accordance with some embodiments. The adhesion layer 22 may be conformally deposited on surfaces of the openings 23 and over top surfaces of the dielectric layer 18. The adhesion layer 22 may also physically contact any conductive features exposed by the openings 23. In some embodiments, the adhesion layer 22 comprises one or more materials such as titanium, titanium nitride, tantalum, tantalum nitride, titanium tungsten, the like, or a combination thereof. Other materials are possible. The adhesion layer 22 may be deposited using a suitable technique, such as PVD, ALD, or the like. In some embodiments, the adhesion layer 22 is formed having a thickness in the range of about 1 nm to about 100 nm, though other thicknesses are possible.

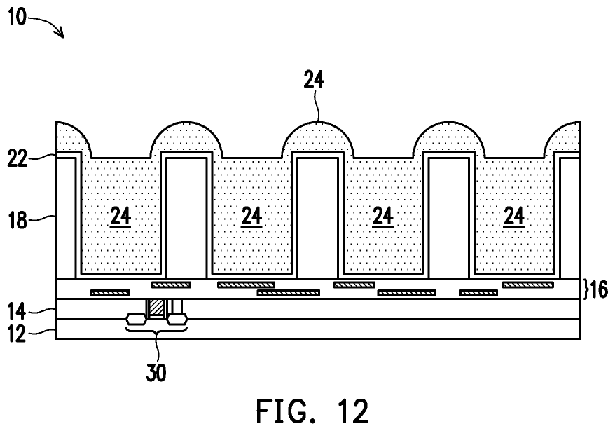

In FIG. 12, a magnetic material 24 is deposited over the adhesion layer 22, in accordance with some embodiments. The magnetic material 24 may fill, partially fill, or overfill the openings 23. For example, FIG. 12 shows an embodiment in which the magnetic material 24 overfills the openings 23 and covers the regions of the dielectric layer 18 between the openings 23. The magnetic material 24 may comprise a conductive ferromagnetic material, such as iron, cobalt, nickel, neodymium, gadolinium, terbium, dysprosium, alloys thereof, combinations thereof, or the like. Other materials are possible. The magnetic material 24 may be deposited using a suitable technique, such as PVD, ALD, or the like.

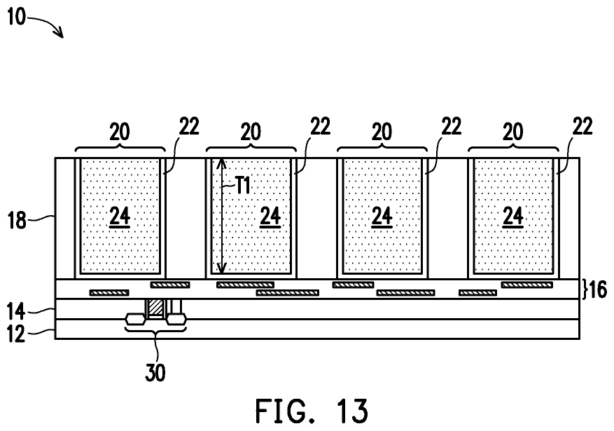

In FIG. 13, a planarization process is performed to remove excess adhesion layer 22 and magnetic material 24, in accordance with some embodiments. The planarization process may include, for example, a Chemical Mechanical Polish (CMP) process, a grinding process, or the like. The remaining portions of the adhesion layer 22 and the magnetic material 24 form the magnetic bonding pads 20. The magnetic bonding pads 20 are formed from a single material (e.g., magnetic material 24) and thus may be considered “single-layer contacts” in some cases. After performing the planarization process, top surfaces of the dielectric layer 18, adhesion layer 22, and magnetic material 24 may be level. In some embodiments, the magnetic material 24 has a thickness Ti in the range of about 10 nm to about 100 μm, though other thicknesses are possible.

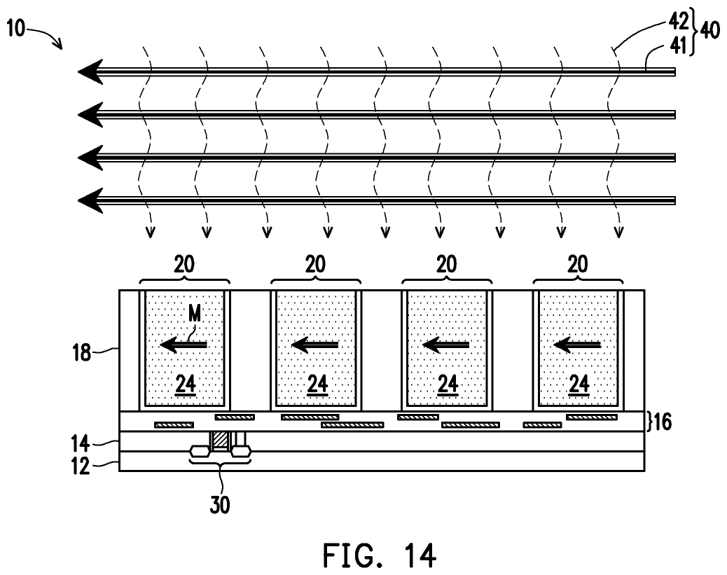

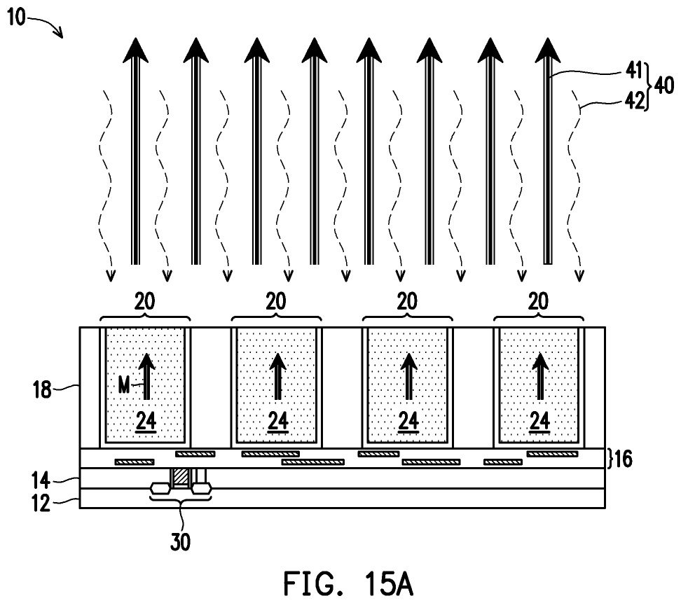

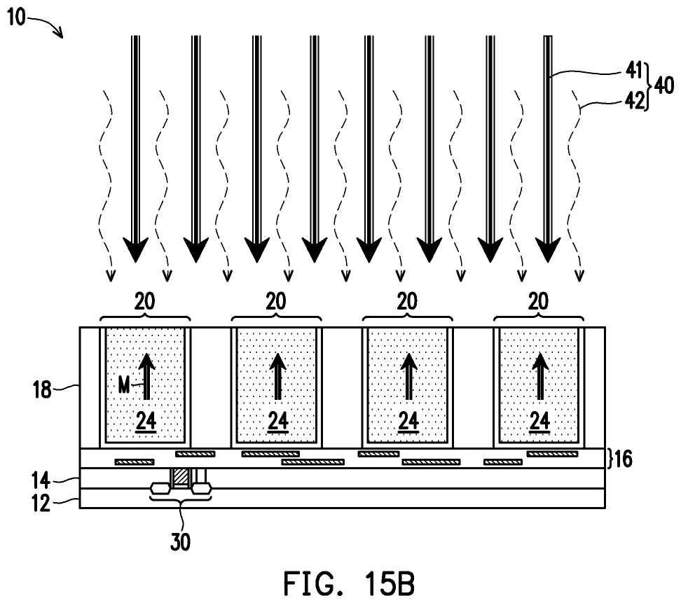

In FIG. 14, a magnetic anneal process 40 is performed to orient the magnetic fields of the magnetic bonding pads 20, in accordance with some embodiments. The magnetic anneal process 40 magnetizes the magnetic bonding pads 20 such that the magnetic bonding pads 20 have magnetic fields that are oriented in approximately the same direction. Orienting the magnetic fields of the magnetic bonding pads 20 using the magnetic anneal process 40 may also strengthen the magnetic fields, in some cases. In some embodiments, the magnetic anneal process 40 comprises heating the wafer 10 using an anneal 42 while subjecting the wafer 10 to an external magnetic field 41. The orientation of the magnetic field 41 corresponds to the desired orientation of the magnetic fields of the magnetic bonding pads 20.

The anneal 42 of the magnetic anneal process 40 comprises heating the wafer 10 using a Rapid Thermal Anneal (RTA) process, a laser anneal process, or another suitable anneal process. In some embodiments, the anneal 42 uses a temperature in the range of about 50° C. to about 1200° C., though other temperatures are possible. In some embodiments, the anneal 42 includes a continuous anneal process using a temperature less than about 400° C. In some embodiments, the anneal 42 includes a pulsed anneal process using a temperature greater than about 400° C. The magnetic field 41 of the magnetic anneal process 40 may be generated using a suitable technique, such as using an electromagnet or the like. In some embodiments, the magnetic field 41 is in the range of about 0.1 T to about 1 T, though other magnetic fields are possible.

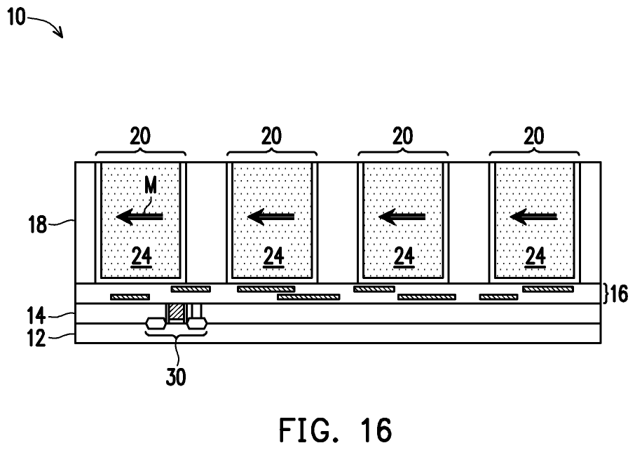

As shown in FIG. 14 by the arrows M, the magnetic field 41 induces magnetic fields of a similar orientation in the magnetic bonding pads 20. FIG. 14 illustrates a lateral magnetic field 41 that induces lateral magnetic fields in the magnetic bonding pads 20, but other magnetic field orientations are possible. As examples, FIGS. 15A and 15B illustrate magnetic anneal processes 40 that induce vertically-oriented magnetic fields in the magnetic bonding pads 20, in accordance with some embodiments. In FIG. 15A, the magnetic field 41 is vertically-oriented such that the north pole of the magnetic field 41 is above the south pole of the magnetic field 41 In other words, the magnetic field 41 extends from the back side of the wafer 10 toward the front side of the wafer 10. Accordingly, as shown by the arrows M, the magnetic fields of the magnetic bonding pads 20 are oriented similarly by the magnetic anneal process 40. In FIG. 15B, the magnetic field 41 is vertically-oriented such that the south pole of the magnetic field 41 is above the north pole of the magnetic field 41 In other words, the magnetic field 41 extends from the front side of the wafer 10 toward the back side of the wafer 10. Accordingly, as shown by the arrows M, the magnetic fields of the magnetic bonding pads 20 are oriented similarly by the magnetic anneal process 40.

FIG. 16 illustrates the wafer 10 with magnetic bonding pads 20 after performing the magnetic anneal process 40, in accordance with some embodiments. As shown in FIG. 16, the magnetic anneal process 40 has induced magnetic fields having the same orientation within the magnetic bonding pads 20. In other embodiments, nonmagnetic bonding pads 21 may be formed in openings 23 rather than magnetic bonding pads 20, similar to the embodiments described previously for FIGS. 5A-6D. The nonmagnetic bonding pads 21 may be formed, for example, by depositing a nonmagnetic material in some openings 23 after the adhesion layer 22 has been deposited, such as the openings 23 in FIG. 11. In some embodiments, the openings 23 in which the nonmagnetic bonding pads 21 are not formed may be covered during deposition of the nonmagnetic material by a photoresist or other masking layer. The nonmagnetic material may be deposited before or after the magnetic material 24. The nonmagnetic material may be a suitable conductive material such as copper, tungsten, ruthenium, the like, or a combination thereof. The nonmagnetic material may be deposited using a suitable technique, such as PVD or ALD. Other materials or deposition techniques are possible.

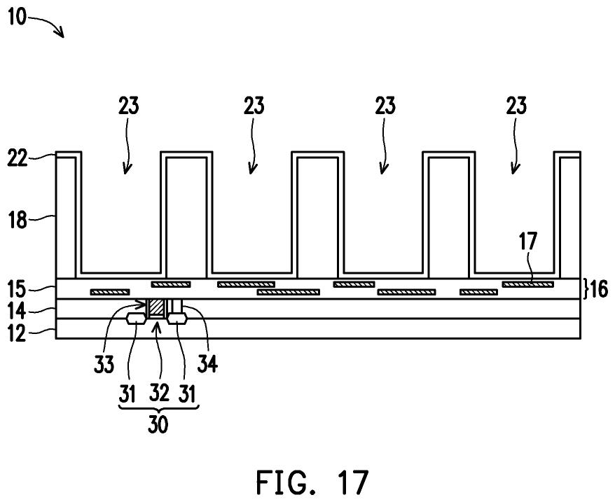

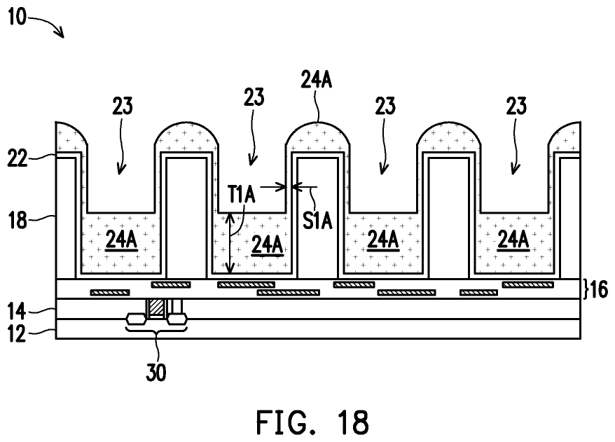

The magnetic bonding pads 20 described for FIGS. 9-16 include a single layer of magnetic material 24, but the in other embodiments, magnetic bonding pads may include two or more layers of different materials. As an example, FIGS. 17 through 20 illustrate intermediate steps in the formation of magnetic bonding pads 50 comprising two layers of material 24A-B, in accordance with some embodiments. The magnetic bonding pads 50 are similar to the magnetic bonding pads 20 described for FIG. 16, except that the magnetic material 24 of the magnetic bonding pads 50 is formed of a layer of a first material 24A and a layer of a second material 24B. In this manner, the magnetic bonding pads 50 may be considered “bi-layer contacts,” in some cases. FIG. 17 illustrates a wafer 10 in which an adhesion layer 22 has been conformally deposited in openings 23, similar to the structure shown in FIG. 11.

In FIG. 18, a layer of first material 24A is deposited into the openings 23, in accordance with some embodiments. As shown in FIG. 18, the first material 24A may partially fill the openings 23. In some embodiments, the layer of first material 24A has a thickness TIA in the range of about 10 nm to about 100 μm, though other thicknesses are possible. In some embodiments, the first material 24A is also deposited on sidewalls of the openings 23 and/or over top surfaces of the dielectric layer 18. In some embodiments, the first material 24A on sidewalls of the openings 23 has a thickness S1A in the range of about 1 nm to about 100 nm, though other thicknesses are possible. In some embodiments, the first material 24A is not deposited on sidewalls of the openings 23 or is removed from sidewalls of the openings 23 using an etching or cleaning process.

In some embodiments, the first material 24A is a conductive material that allows for electrical connection to the interconnect structure 16 and/or the conductive plugs 34. In some embodiments, the first material 24A comprises a conductive ferromagnetic material, such as iron, cobalt, nickel, neodymium, gadolinium, terbium, dysprosium, alloys thereof, combinations thereof, or the like. In some embodiments, the first material 24A is a conductive nonmagnetic material, such as tantalum, ruthenium, tungsten, platinum, copper, aluminum, titanium, alloys thereof, combinations thereof, or the like. In some embodiments, the conductive nonmagnetic material is an antiferromagnetic material, which may be formed of materials such as platinum, iridium, manganese, alloys thereof, or the like. Other materials are possible. The first material 24A may be deposited using a suitable technique, such as PVD, ALD, or the like.

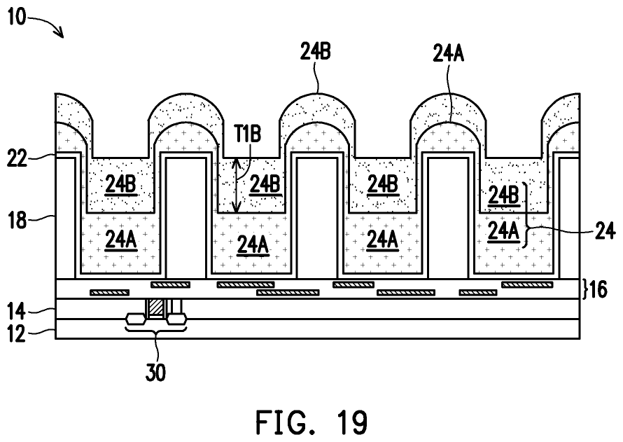

In FIG. 19, a layer of second material 24B is deposited over the layer of first material 24A, in accordance with some embodiments. The layer of second material 24B and the layer of first material 24A collectively form the magnetic material 24 of the magnetic bonding pads 50. The second material 24B may fill, partially fill, or overfill the openings 23. In some embodiments, the layer of second material 24B has a thickness T1B in the range of about 10 nm to about 100 μm, though other thicknesses are possible. In some embodiments, the second material 24B is also deposited on sidewalls of the openings 23 and/or over top surfaces of the dielectric layer 18. The second material 24B may be deposited using a suitable technique, such as PVD, ALD, or the like.

In some embodiments, the second material 24B is a conductive magnetic material, such as iron, cobalt, nickel, neodymium, gadolinium, terbium, dysprosium, another ferromagnetic material, alloys thereof, combinations thereof, or the like. In embodiments in which the first material 24A is an antiferromagnetic material, the layer of first material 24A may act as a pinning layer for the layer of second material 24B. For example, in some embodiments, the first material 24A may be platinum and the second material 24B may be cobalt. In some cases, the use of an antiferromagnetic pinning layer may allow for stronger or more robust magnetic fields within the magnetic bonding pads. Other materials or combinations of materials are possible.

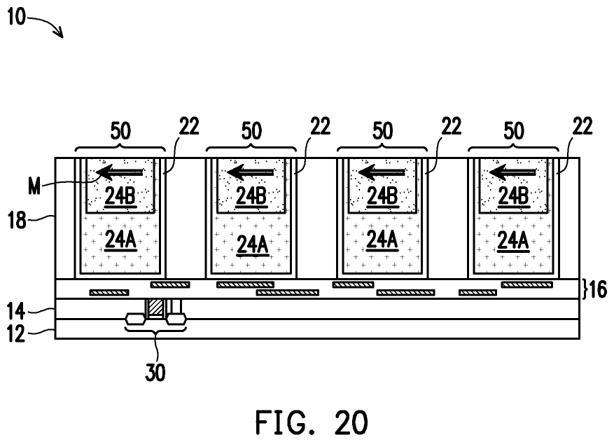

In FIG. 20, a planarization process (e.g., a CMP process, grinding process, or the like) is performed to remove excess adhesion layer 22, first material 24A, and second material 24B, in accordance with some embodiments. After performing the planarization process, top surfaces of the dielectric layer 18, adhesion layer 22, first material 24A, and/or second material 24B may be level. The remaining portions of the adhesion layer 22, first material 24A, and second material 24B form the magnetic bonding pads 50.

Further in FIG. 20, a magnetic anneal process is performed to orient the magnetic fields of the magnetic bonding pads 50, in accordance with some embodiments. The magnetic anneal process may be similar to the magnetic anneal process 40 described previously for FIGS. 14-15B. FIG. 20 illustrates the magnetic fields of the magnetic bonding pads 50 as having a lateral orientation (see arrows M), but the magnetic fields may have another orientation in other embodiments.

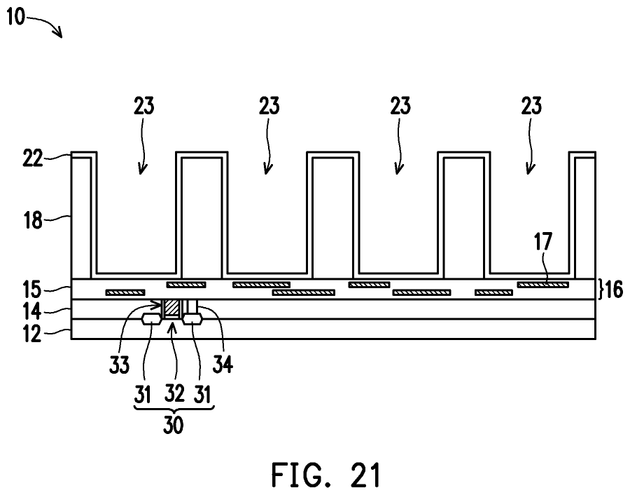

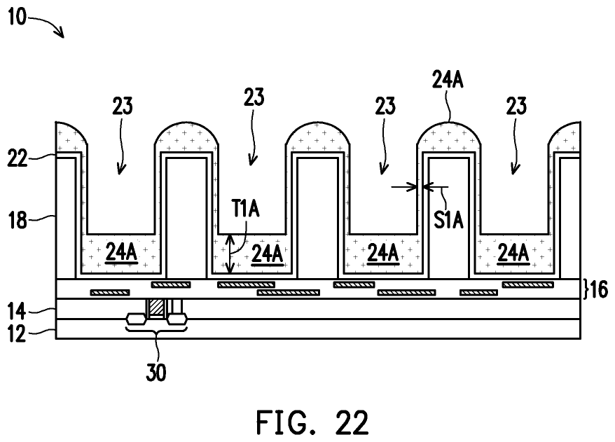

FIGS. 21 through 25 illustrate intermediate steps in the formation of magnetic bonding pads 60 comprising three layers of material 24A-C, in accordance with some embodiments. The magnetic bonding pads 60 are similar to the magnetic bonding pads 20 described for FIG. 16 or the magnetic bonding pads 50 described for FIG. 20, except that the magnetic material 24 of the magnetic bonding pads 50 is formed of a layer of a first material 24A, a layer of a second material 24B, and a layer of third material 24C. In this manner, the magnetic bonding pads 50 may be considered “tri-layer contacts,” in some cases. In other embodiments, the magnetic bonding pads may be formed of more than three layers of material or materials in other combinations than described herein. FIG. 21 illustrates a wafer 10 in which an adhesion layer 22 has been conformally deposited in openings 23, similar to the structure shown in FIG. 11 or FIG. 17.

In FIG. 22, a layer of first material 24A is deposited into the openings 23, in accordance with some embodiments. As shown in FIG. 22, the first material 24A may partially fill the openings 23. In some embodiments, the layer of first material 24A has a thickness TIA in the range of about 10 nm to about 100 μm, though other thicknesses are possible. In some embodiments, the first material 24A is also deposited on sidewalls of the openings 23 and/or over top surfaces of the dielectric layer 18. In some embodiments, the first material 24A on sidewalls of the openings 23 has a thickness S1A in the range of about 1 nm to about 100 nm, though other thicknesses are possible. In some embodiments, the first material 24A is not deposited on sidewalls of the openings 23 or is removed from sidewalls of the openings 23 using an etching or cleaning process.

In some embodiments, the first material 24A is a conductive material that allows for electrical connection to the interconnect structure 16 and/or the conductive plugs 34. In some embodiments, the first material 24A comprises a conductive ferromagnetic material, such as iron, cobalt, nickel, neodymium, gadolinium, terbium, dysprosium, alloys thereof, combinations thereof, or the like. In some embodiments, the first material 24A is a conductive nonmagnetic material, such as tantalum, ruthenium, tungsten, platinum, copper, aluminum, titanium, alloys thereof, combinations thereof, or the like. In some embodiments, the conductive nonmagnetic material is an antiferromagnetic material, which may be formed of materials such as platinum, iridium, manganese, alloys thereof, or the like. Other materials are possible. The first material 24A may be deposited using a suitable technique, such as PVD, ALD, or the like.

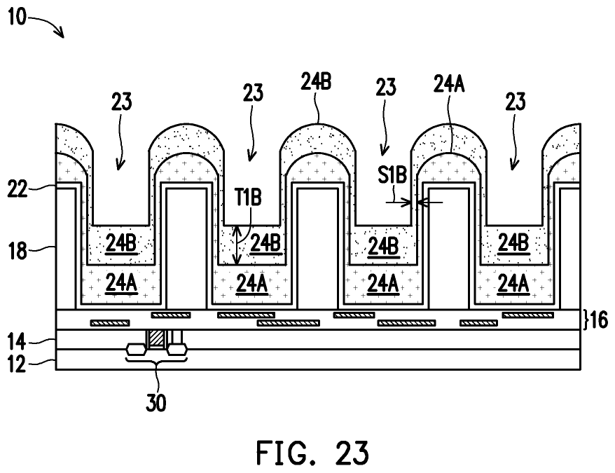

In FIG. 23, a layer of second material 24B is deposited over the layer of first material 24A, in accordance with some embodiments. The second material 24B may partially fill the openings 23. In some embodiments, the layer of second material 24B has a thickness T1B in the range of about 10 nm to about 100 μm, though other thicknesses are possible. In some embodiments, the second material 24B is also deposited on sidewalls of the openings 23 and/or over top surfaces of the dielectric layer 18. In some embodiments, the second material 24B on sidewalls of the openings 23 has a thickness S1B in the range of about 1 nm to about 100 nm, though other thicknesses are possible. In some embodiments, the second material 24B is not deposited on sidewalls of the openings 23 or is removed from sidewalls of the openings 23 using an etching or cleaning process.

In some embodiments, the second material 24B is a conductive magnetic material, such as iron, cobalt, nickel, neodymium, gadolinium, terbium, dysprosium, another ferromagnetic material, alloys thereof, combinations thereof, or the like. Other materials are possible. In embodiments in which the first material 24A is an antiferromagnetic material, the layer of first material 24A may act as a pinning layer for the layer of second material 24B. For example, in some embodiments, the first material 24A may be platinum and the second material 24B may be cobalt. Other materials or combinations of materials are possible. The second material 24B may be deposited using a suitable technique, such as PVD, ALD, or the like.

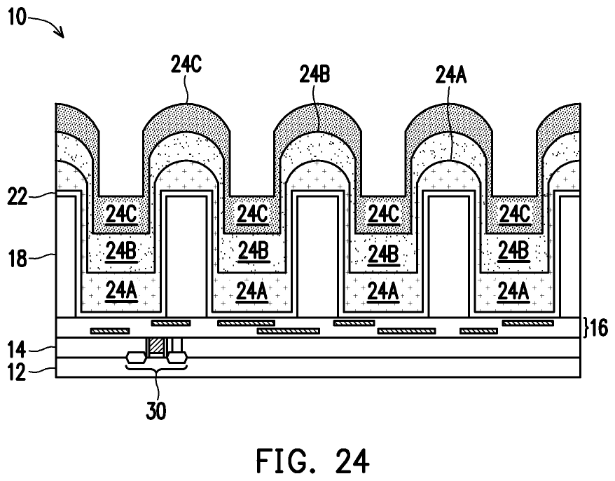

In FIG. 24, a layer of third material 24C is deposited over the layer of second material 24B, in accordance with some embodiments. The third material 24C may fill, partially fill, or overfill the openings 23. In some embodiments, the layer of third material 24C has a thickness TIC in the range of about 10 nm to about 100 μm, though other thicknesses are possible. In some embodiments, the third material 24C is also deposited on sidewalls of the openings 23 and/or over top surfaces of the dielectric layer 18. The layer of third material 24C, the layer of second material 24B, and the layer of first material 24A collectively form the magnetic material 24 of the magnetic bonding pads 60.

In some embodiments, the third material 24C comprises a conductive ferromagnetic material, such as iron, cobalt, nickel, neodymium, gadolinium, terbium, dysprosium, alloys thereof, combinations thereof, or the like. In some embodiments, the third material 24C is a conductive nonmagnetic material, such as tantalum, ruthenium, tungsten, platinum, copper, aluminum, titanium, alloys thereof, combinations thereof, or the like. In some embodiments, the conductive nonmagnetic material is an antiferromagnetic material, which may be formed of materials such as platinum, iridium, manganese, alloys thereof, or the like. Other materials are possible. The third material 24C may be deposited using a suitable technique, such as PVD, ALD, or the like.

In embodiments in which the third material 24C is an antiferromagnetic material, the layer of third material 24C may act as a pinning layer for the layer of second material 24B. For example, in some embodiments, the first material 24A may be platinum and the second material 24B may be cobalt. In some cases, the use of an antiferromagnetic pinning layer may allow for stronger or more robust magnetic fields within the magnetic bonding pads. Other materials or combinations of materials are possible. In some embodiments, the third material 24C is the same as the first material 24A. For example, the layer of second material 24B may be a ferromagnetic material and the layer of first material 24A and the layer of third material 24C may both be the same antiferromagnetic material. In some cases, sandwiching a ferromagnetic material between two antiferromagnetic pinning layers may allow for stronger or more robust magnetic fields within the magnetic bonding pads.

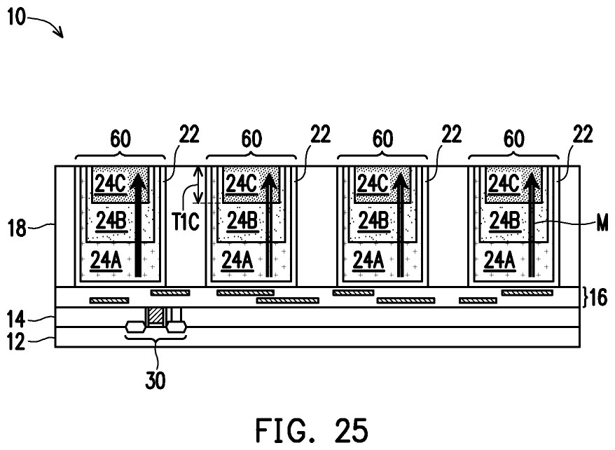

In FIG. 25, a planarization process (e.g., a CMP process, grinding process, or the like) is performed to remove excess adhesion layer 22, first material 24A, second material 24B, and third material 24C, in accordance with some embodiments. After performing the planarization process, top surfaces of the dielectric layer 18, adhesion layer 22, first material 24A, second material 24B, and/or third material 24C may be level. The remaining portions of the adhesion layer 22, first material 24A, second material 24B, and third material 24C form the magnetic bonding pads 60.

Further in FIG. 25, a magnetic anneal process is performed to orient the magnetic fields of the magnetic bonding pads 60, in accordance with some embodiments. The magnetic anneal process may be similar to the magnetic anneal process 40 described previously for FIGS. 14-15B. FIG. 25 illustrates the magnetic fields of the magnetic bonding pads 60 as having a vertical orientation (see arrows M), but the magnetic fields may have another orientation in other embodiments.

Embodiments may achieve advantages. By bonding structures (e.g., wafers, dies, etc.) using magnetic bonding pads, misalignment during the bonding process can be reduced. For example, magnetic bonding pads can be formed in a first wafer and a second wafer. The magnetic fields of the magnetic bonding pads can be oriented such that the magnetic bonding pads on the second wafer are attracted to corresponding magnetic bonding pads on the first wafer. The magnetic attraction between the magnetic bonding pads pulls the wafers toward each other to minimize or reduce misalignment. In this manner, the wafers can “self-align” during the bonding process to achieve greater alignment accuracy. The embodiments described herein may reduce contact resistance or increase contact area of electrical connections between bonded structures, which can improve device efficiency and device performance. Embodiments described herein can increase yield, and can allow for bonding pads to be formed having a smaller pitch. In this manner, device density can be increased and device size can be reduced. The embodiments described herein may be used as part of a FEOL process and/or a BEOL process.

In accordance with some embodiments of the present disclosure, a method includes forming first bonding pads over a first substrate, wherein the first bonding pads include a layer of ferromagnetic material, wherein each first bonding pad produces a respective magnetic field having a first orientation; and bonding second bonding pads to the first bonding pads using metal-to-metal bonding. In an embodiment, each second bonding pad produces a respective magnetic field having a second orientation. In an embodiment, the first orientation and the second orientation are parallel. In an embodiment, the first bonding pads further include a layer of antiferromagnetic material. In an embodiment, the first substrate includes an interconnect structure, wherein the first bonding pads are electrically connected to the interconnect structure. In an embodiment, forming first bonding pads includes performing a magnetic annealing process on the layer of ferromagnetic material. In an embodiment, bonding second bonding pads to the first bonding pads includes bringing the second bonding pads toward the first bonding pads until the second bonding pads contact the first bonding pads, wherein a misalignment between the first bonding pads and the second bonding pads decreases as the second bonding pads are brought toward the first bonding pads until the second bonding pads contact the first bonding pads. In an embodiment, the first bonding pads are magnetically attracted to the second bonding pads.

In accordance with some embodiments of the present disclosure, a method includes forming a first bonding pad, which includes forming a recess in a first dielectric layer; filling the recess with magnetic material; and performing a magnetic annealing process on the magnetic material; and bonding the first bonding pad to a second bonding pad. In an embodiment, forming the recess exposes a conductive feature disposed below the first dielectric layer. In an embodiment, the magnetic annealing process induces a magnetic field in the first bonding pad. In an embodiment, the magnetic material includes cobalt. In an embodiment, the magnetic material includes multiple layers. In an embodiment, the magnetic annealing process includes heating the magnetic material while subjecting the magnetic material to an external magnetic field. In an embodiment, the second bonding pad is surrounded by a second dielectric layer, and further including bonding the first dielectric layer to the second dielectric layer.

In accordance with some embodiments of the present disclosure, a device includes first bonding pads over a first interconnect structure, wherein each first bonding pad is magnetized in a first orientation; and second bonding pads over a second interconnect structure, wherein each second bonding pad is magnetized in a second orientation, wherein each second bonding pad is bonded to a respective first bonding pad. In an embodiment, the first orientation and the second orientation are the same orientation. In an embodiment, the first orientation is a lateral direction. In an embodiment, the first bonding pads are electrically isolated from the first interconnect structure. In an embodiment, each first bonding pad includes a layer of ferromagnetic material sandwiched between two layers of antiferromagnetic material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming first bonding pads over a first substrate, wherein the first bonding pads comprise a layer of ferromagnetic material, wherein each first bonding pad produces a respective magnetic field having a first orientation; and
bonding second bonding pads to the first bonding pads using metal-to-metal bonding.

2. The method of claim 1, wherein each second bonding pad produces a respective magnetic field having a second orientation.

3. The method of claim 2, wherein the first orientation and the second orientation are parallel.

4. The method of claim 1, wherein the first bonding pads further comprise a layer of antiferromagnetic material.

5. The method of claim 1, wherein the first substrate comprises an interconnect structure, wherein the first bonding pads are electrically connected to the interconnect structure.

6. The method of claim 1, wherein forming first bonding pads comprises performing a magnetic annealing process on the layer of ferromagnetic material.

7. The method of claim 1, wherein bonding second bonding pads to the first bonding pads comprises bringing the second bonding pads toward the first bonding pads until the second bonding pads contact the first bonding pads, wherein a misalignment between the first bonding pads and the second bonding pads decreases as the second bonding pads are brought toward the first bonding pads until the second bonding pads contact the first bonding pads.

8. The method of claim 1, wherein the first bonding pads are magnetically attracted to the second bonding pads.

9. A method comprising:
forming a first bonding pad, comprising:
forming a recess in a first dielectric layer;
filling the recess with magnetic material; and
performing a magnetic annealing process on the magnetic material; and
bonding the first bonding pad to a second bonding pad.

10. The method of claim 9, wherein forming the recess exposes a conductive feature disposed below the first dielectric layer.

11. The method of claim 9, wherein the magnetic annealing process induces a magnetic field in the first bonding pad.

12. The method of claim 9, wherein the magnetic material comprises cobalt.

13. The method of claim 9, wherein the magnetic material comprises a plurality of layers.

14. The method of claim 9, wherein the magnetic annealing process comprises heating the magnetic material while subjecting the magnetic material to an external magnetic field.

15. The method of claim 9, wherein the second bonding pad is surrounded by a second dielectric layer, and further comprising bonding the first dielectric layer to the second dielectric layer.

16. A device comprising:
a plurality of first bonding pads over a first interconnect structure, wherein each first bonding pad is magnetized in a first orientation; and
a plurality of second bonding pads over a second interconnect structure, wherein each second bonding pad is magnetized in a second orientation, wherein each second bonding pad is bonded to a respective first bonding pad.

17. The device of claim 16, wherein the first orientation and the second orientation are the same orientation.

18. The device of claim 16, wherein the first orientation is a lateral direction.

19. The device of claim 16, wherein the first bonding pads are electrically isolated from the first interconnect structure.

20. The device of claim 16, wherein each first bonding pad comprises a layer of ferromagnetic material sandwiched between two layers of antiferromagnetic material.
